(19) United States
(12) Patent Application Publication
(10) Pub. No.: US 2013/0125820 A1
(43) Pub. Date: May 23, 2013

(54) CHEMICAL VAPOR DEPOSITION OR EPITAXIAL-LAYER GROWTH REACTOR AND SUPPORTER THEREOF

(71) Applicants: Gerald Zheyao YIN, Shanghai (CN); Yong JIANG, Shanghai (CN)

(72) Inventors: Gerald Zheyao YIN, Shanghai (CN); Yong JIANG, Shanghai (CN)

(21) Appl. No.: 13/681,768

(22) Filed: Nov. 20, 2012

(30) Foreign Application Priority Data
Nov. 23, 2011 (CN) 201110375777.2

(51) Int. Cl. C23C 16/458; C30B 25/12

(52) U.S. Cl. CPC C23C 16/458; C30B 25/12
USPC 118/730

(57) ABSTRACT

A chemical vapor deposition or epitaxial-layer growth reactor includes a reaction chamber. At least one substrate carrier and a supporter for supporting the substrate carrier are provided in the reaction chamber. The substrate carrier includes a first surface and a second surface. The second surface of the substrate carrier is provided with at least one recess concaved inwardly. The supporter includes: a spindle part; a supporting part connected to one end of the spindle part and extending outwardly from the periphery of the spindle part, the supporting part including a supporting surface; and a plug-in part connected to the spindle part and extending by a height towards the first surface of the substrate carrier, the plug-in part of the supporter being inserted detachably in the recess, so as to enable the substrate carrier to be placed on and supported by the supporter.

### FIELD OF THE INVENTION

The present application relates to making semiconductor devices, and more particularly to an apparatus for growing epitaxial layers or performing chemical vapor deposition on underlying material such as substrate.

### BACKGROUND OF THE INVENTION

In a production process of growing epitaxial layers or performing chemical vapor deposition on underlying material such as substrate, designs of reactors are extremely important. In the prior art, the reactors have various designs, including horizontal reactors in which substrates are mounted at an angle to inflowing reactant gases; horizontal reactors with planetary rotation in which reactant gases pass across substrates horizontally; and vertical reactors in which substrates are placed on a substrate carrier within a reaction chamber and are rotated at a relatively high speed as reactant gases are injected downwardly onto the substrates. The vertical reactors with high-speed rotation are among the most commercially important MOCVD reactors.

For example, a Chinese patent for invention (Chinese patent No. 01822507.1) titled “susceptorless reactor for growing epitaxial layers on substrates by chemical vapor deposition” discloses a susceptorless reactor, as shown in FIG. 1, which includes a reaction chamber, a rotatable spindle 400, a heater 140 for heating the substrates, and a substrate carrier 300 for supporting the substrates. The spindle 400 includes a top surface 481 and a spindle wall 482, and the substrate carrier 300 includes a central recess 390. When the substrate carrier 300 is mounted to the spindle 400, the spindle 400 is inserted into the central recess 390 until there is a tight fit between the spindle wall 482 and the wall of the recess 390 to generate a friction force for holding the substrate carrier 300 in a depositing position. That is, the substrate carrier 300 is held on the top end of the spindle 400, and is brought to rotate along with the spindle 400 by friction force.

However, in the practical technical process, it is difficult for the above-mentioned reactor to hold the substrate carrier 300 on the spindle 400 rotating at high speed and enable the synchronous rotation of the substrate carrier 300 and the spindle 400 merely by friction force, for example, slipping may occur due to insufficient friction force. If a holding apparatus is additionally provided in order to solve the problem, the complexity of the system may be increased. Furthermore, due to the limitation of the diameter of the spindle 400, it is hard during the deposition to ensure that the substrate carrier 300 can be kept in a state of balance all along. If the gravity center of the substrate carrier 300 loses its balance during the deposition to sway, the resultant epitaxial layer growing on the substrate is uneven. Further, since there is a tight fit between the spindle wall 482 and the wall of the recess 390, and the substrate processing is generally performed in a high-temperature environment, the spindle 400 may go through thermal expansion. In the event that the thermal expansion coefficient of the spindle 400 is higher than that of the substrate carrier 300, the recess 390 would be damaged under the pressure generated from the thermal expansion of the spindle 400, which may finally result in the split of the whole substrate carrier 300. Lastly, during the deposition, the rotation speed of the spindle 400 is generally different from that of the substrate carrier 300, that is, there is a difference between the two rotation speeds of them, so that the position of the substrate in the reactor cannot be measured accurately and thus the temperature of the substrate can neither be measured precisely nor be controlled further.

### SUMMARY OF THE INVENTION

An object of the present application is to provide a reactor, in which a substrate carrier can rotate stably and reliably in substrate processing, and cannot be damaged by the expansion pressure of a heated and expanded supporter, therefore improving the reliability of the whole reactor.

Another object of the present application is to provide a supporter applicable in the reactor, which can be detachably connected to a substrate carrier, and support the substrate carrier evenly and reliably while driving the substrate carrier to rotate evenly and reliably in substrate processing.

In order to achieve the above objects, according to an aspect of the present application, the present application provides a chemical vapor deposition or epitaxial-layer growth reactor including a reaction chamber in which a substrate carrier and a supporter for supporting the substrate carrier are provided, wherein

the substrate carrier includes a first surface and a second surface, the first surface is configured to place several substrates to be processed thereon; the second surface of the substrate carrier is provided with at least one recess concaved inwardly;

the supporter includes: a spindle part; a supporting part connected to one end of the spindle part and extending outwardly from the periphery of the spindle part, the supporting part including a supporting surface; and at least one plug-in part connected to the spindle part and extending by a height towards the first surface of the substrate carrier; and

the at least one plug-in part of the supporter is inserted detachably into the at least one recess, so as to enable the substrate carrier to be placed on and supported by the supporter, and in a supporting case, the supporting surface of the supporting part at least partially contacts with at least a part of the second surface of the substrate carrier, so that the substrate carrier is supported by the supporting surface in contact with the substrate carrier.

According to another aspect of the present application, the present application provides a chemical vapor deposition or epitaxial-layer growth reactor including a reaction chamber in which a substrate carrier and a supporter for supporting the substrate carrier are provided, wherein

the substrate carrier includes a first surface and a second surface, the first surface is configured to place several substrates to be processed thereon; the second surface of the substrate carrier is provided with at least one recess concaved inwardly;

the supporter includes: a spindle part including a top end, the top end including a supporting surface; and at least one plug-in part connected to the spindle part and extending by a height towards the first surface of the substrate carrier; and

the at least one plug-in part is inserted detachably into the at least one recess, so as to enable the substrate carrier to be placed on and supported by the supporter, and in a supporting case, the supporting surface at least partially contacts with at least a part of the second surface of the substrate carrier, so that the substrate carrier is supported by the supporting surface in contact with the substrate carrier.

According to yet another aspect of the present application, the present application further provides a supporter for supporting a substrate carrier and being applicable in a chemical vapor deposition or epitaxial-layer growth reactor, wherein

the substrate carrier includes a first surface for placing several substrates to be processed thereon, and a second surface provided with at least one recess concaved inwardly, and

wherein the supporter includes:
a spindle part;
a supporting part connected to one end of the spindle part and extending outwardly from the periphery of the spindle part, the supporting part including a supporting surface; and
at least one plug-in part connected to the spindle part and extending by a height towards the first surface of the substrate carrier.

According to still another aspect of the present application, the present application further provides a supporter for supporting a substrate carrier and being applicable in a chemical vapor deposition or epitaxial-layer growth reactor, wherein

the substrate carrier includes a first surface for placing several substrates to be processed thereon, and a second surface provided with at least one recess concaved inwardly, and

wherein the supporter includes:
a spindle part including a top end, the top end including a supporting surface; and
at least one plug-in part connected to the spindle part and extending by a height towards the first surface of the substrate carrier; and

wherein the at least one plug-in part is inserted detachably into the at least one recess, so as to enable the substrate carrier to be placed on and supported by the supporter, and in a supporting case, the supporting surface of the supporting part at least partially contacts with at least a part of the second surface of the substrate carrier, so that the substrate carrier is supported by the supporting surface in contact with the substrate carrier.

The reactor and the supporter according to the present application have many advantages. First, the whole substrate carrier cannot sway from side to side due to the instability of gravity center in the substrate processing after being placed on the supporter, that is, the supporter can force the substrate carrier to rotate synchronously and smoothly. Furthermore, since the rotation of the substrate carrier is realized under the force (pushing force or resisting force) applied by the plug-in part in the direction of the horizontal plane, thereby, the phenomenon of “friction slipping” between the substrate carrier and the plug-in part in the prior art may not arise. Further, since a certain clearance is allowed to exist between the plug-in part and the recess after they are connected and engaged with each other, the clearance allows the thermal expansion of the plug-in part 24 in a high-temperature processing environment, thereby preventing the damages to the substrate carrier under the pressure of the plug-in part heated and thus expanded due to the friction fit therebetween which would be otherwise occur in the prior art. Lastly, the arrangement of the present application may further facilitate measuring the exact position and temperature of the substrates located in the enclosed reaction chamber in real time and in situ in a substrate processing.

### BRIEF DESCRIPTION OF THE DRAWINGS

Upon reading the detailed description of non-limiting embodiments made with references to the accompanying drawings, other features, objects and advantages of the present application will become more apparent. In the accompanying drawings:

FIG. 1 shows a susceptorless reactor for growing epitaxial layers on substrates by chemical vapor deposition in the prior art;

FIG. 2A shows a schematic cross-sectional front view of a reactor according to the present application;

FIG. 2B is a schematic perspective view of a substrate carrier in the embodiment shown in FIG. 2A;

FIG. 2C is a schematic perspective view of a supporter in the embodiment shown in FIG. 2A;

FIG. 3A is a schematic cross-sectional view of the reactor in FIG. 2A taken along line I-I and viewed from bottom along direction A;

FIG. 3B is a schematic cross-sectional bottom view of a reactor according to another embodiment of the present application;

FIG. 3C is a schematic cross-sectional bottom view of a reactor according to another embodiment of the present application;

FIG. 4A is a schematic perspective view of a supporter according to another embodiment of the present application;

FIG. 4B is a schematic perspective view of a substrate carrier according to another

FIG. 4C is a schematic cross-sectional view illustrating the connection between the supporter shown in FIG. 4A and the substrate carrier shown in FIG. 4B;

FIG. 4D is a schematic perspective view of a substrate carrier according to another embodiment of the present application;

FIG. 4E is a schematic perspective view illustrating the connection and engagement between the supporter shown in FIG. 4A and the substrate carrier shown in FIG. 4D;

FIG. 5A is a schematic perspective view of a supporter according to another embodiment of the present application;

FIG. 5B is a schematic perspective view of a substrate carrier according to another embodiment of the present application;

FIG. 5C is a schematic perspective view illustrating the connection and engagement between the supporter shown in FIG. 5A and the substrate carrier shown in FIG. 5B;

FIG. 5D is a schematic perspective view of a substrate carrier according to another embodiment of the present application; and

FIG. 5E is a schematic perspective view illustrating the connection and engagement between the supporter shown in FIG. 5A and the substrate carrier shown in FIG. 5D.

### DETAILED DESCRIPTION

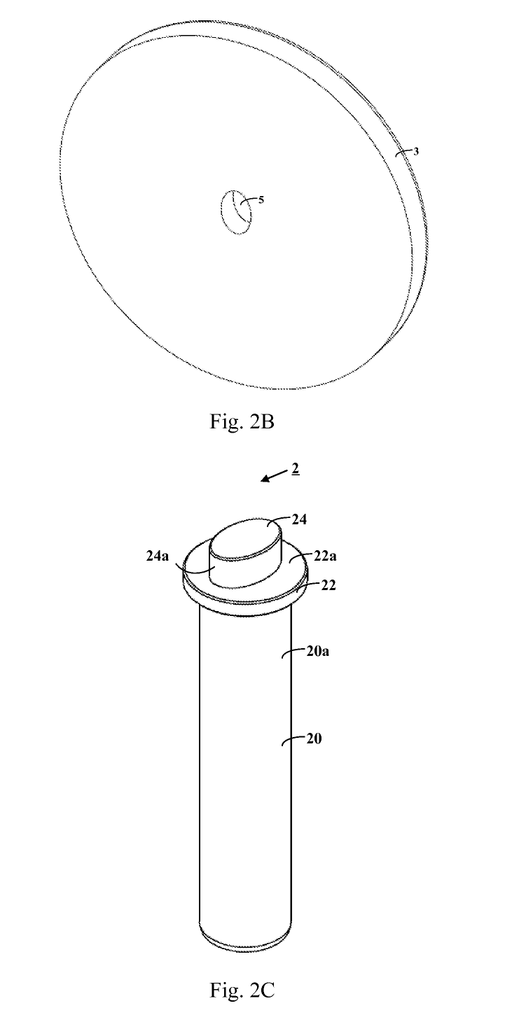

FIG. 2A shows a schematic cross-sectional front view of a reactor according to an embodiment of the present application. The reactor can be used in chemical vapor deposition or epitaxial-layer growth, however, it should be appreciated that it is not limited thereto. As shown in FIG. 2A, the reactor includes a reaction chamber 1 in which at least one substrate carrier 3 and a supporter 2 for supporting the substrate carrier 3 are provided. A transport opening P through which the substrate carrier 3 is transported into or out of the reaction chamber 1 is provided in the side wall of the reaction chamber 1. The substrate carrier 3 includes a first surface 3a for placing several substrates to be processed thereon, and a second surface 3b. Preferably, the first surface 3a is provided with several grooves or notches (not shown) for placing substrates (not shown) to be processed. The second surface 3b of the substrate carrier 3 is provided with a recess 5 concaved inwardly.

Generally, before a substrate processing is performed in the reaction chamber 1, the substrate carrier 3 is located outside of the reaction chamber 1, and several substrates to be processed (not shown) are placed on the substrate carrier 3 in advance. Then, the substrate carrier 3 is transported into the reaction chamber 1 through the transport opening P by a robot or other means, and then is detachably placed on and supported by the supporter 2, being ready for the substrate processing. The substrate carrier 3 is supported by the supporter 2 throughout the following substrate processing. The supporter 2 is also connected to a rotary mechanism M including a motor. In the processing, the rotary mechanism M drives the supporter 2 to rotate, which in turn forces or drives the substrate carrier 3 to rotate. After the substrate processing is finished, the rotation of the rotary mechanism M is ceased, so that the supporter 2 and the substrate carrier 3 do not rotate anymore. The substrate carrier 3 is detached from the supporter 2 by the robot or other means, and then is sent out of the reaction chamber 1 through the transport opening P.

Referring to FIG. 2B, FIG. 2B is a schematic perspective view of the substrate carrier 3 in the embodiment shown in FIG. 2A. The substrate carrier 3 is of an approximate disc shape, which includes a first surface 3a and a second surface 3b substantially parallel or opposite to each other. A recess 5 concaved inwardly (i.e. towards the first surface 3a) is provided at a proper position (for example, at the central region) on the second surface 3b of the substrate carrier.

Referring to FIG. 2C, FIG. 2C is a schematic perspective view of the supporter 2 in the embodiment shown in FIG. 2A. The supporter 2 includes: a spindle part 20; a supporting part 22 connected to one end of the spindle part 20 and extending outwardly from the periphery of the spindle part 20, the supporting part 22 including a supporting surface 22a; and a plug-in part 24 connected to the supporting part 22 and protruding outwardly by a certain distance or height from the supporting surface 22a.

It is convenient to connect/disconnect the supporter 2 with/from the substrate carrier 3 according to the present application. The supporter 2 and the substrate carrier 3 are not fixedly connected with each other, and can be maintained in synchronous rotation when a substrate processing is performed in the reaction chamber 1. For this purpose, the plug-in part 24 of the supporter 2 can be inserted detachably into the recess 5 described above, so as to enable the substrate carrier 3 to be placed on and supported by the supporter 2. In such a position and state, at least part of the supporting surface 22a of the supporting part 22 contacts with at least part of the second surface 3b of the substrate carrier 3, so that the substrate carrier 3 is supported by way of the supporting surface 22a in contact therewith. The above-mentioned supporting part 22 is arranged at and connected with one end of the spindle part 20. The supporting part 22 extends outwardly from the periphery of the spindle part 20 by a certain distance to form a structure like “a shoulder” or “a supporting shelf”, so that the substrate carrier 3 placed thereon may be supported or held in equilibrium in the Z-axis direction. Supporting part 22 may be a supporting arrangement having various shapes or structures, for example, a supporting arrangement being of cylindrical shape as shown, or cubical shape or any other irregular shape. The supporting part 22 includes the supporting surface 22a functioning to support the substrate carrier 3 when the substrate carrier 3 is supported by the supporter 2. Preferably, the supporting surface 22a is substantially a flat surface, and the surface of the substrate carrier 3 being in contact with the supporting surface 22a is also designed to be a flat surface, so that the supporting surface 22a can support the substrate carrier 3 stably.

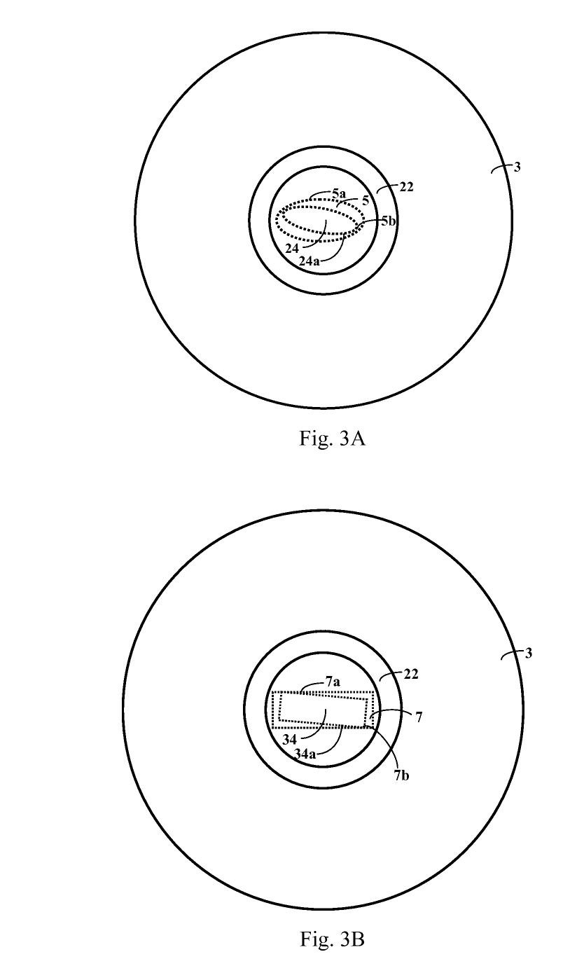

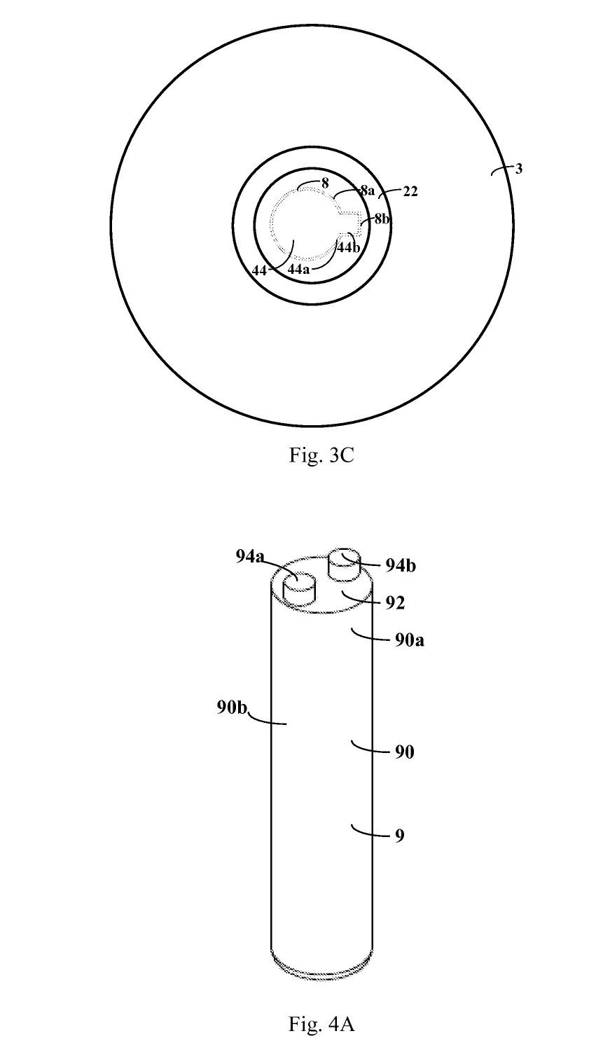

Furthermore, in the embodiment of the present application, in performing a substrate processing after the substrate carrier 3 is placed on the supporter 2, the substrate carrier 3 is generally required to rotate smoothly at a certain speed. The rotation movement of the substrate carrier 3 is realized in that the plug-in part 24 of the supporter 2 pushes or drives or forces the substrate carrier 3 in a direction of a horizontal plane defined by the X and Y-axes, rather than by a friction force between the substrate carrier 3 and the supporter 2 in the prior art. Please referring to FIG. 3A, FIG. 3A is a schematic cross-sectional view of the reactor in FIG. 2A taken along line I-I and viewed from bottom along direction A, which shows the position relationship between the plug-in part 24 of the supporter 2 and the recess 5 of the substrate carrier 3 after being connected and engaged with each other. The plug-in part 24 in the embodiment as illustrated is an elliptic cylinder having an elliptic cross section in the horizontal plane, and a concaved space formed in the recess 5 corresponding to the plug-in part 24 is also an elliptic cylinder having an elliptic cross section in the horizontal plane. The plug-in part 24 includes a periphery 24a, and the recess 5 of the substrate carrier 3 includes an internal circumferential wall 5a. The elliptic area surrounded by the periphery 24a of the plug-in part 24 is smaller than or slightly smaller than the elliptic area surrounded by the internal circumferential wall 5a of the recess 5, in other words, the volume of the plug-in part 24 is smaller than the holding capacity of the concaved space formed in the recess 5. Thus, the plug-in part 24 can be easily inserted into the recess 5, and there is a certain clearance between at least parts of them after they are engaged with each other. In this way, it becomes possible for the substrate carrier 3 to be detachably placed onto the plug-in part 24. In addition, since the plug-in part 24 may be driven to rotate by the rotary mechanism M located under the plug-in part 24, so that the position of the plug-in part 24 on the horizontal plane can be adjusted. When the plug-in part 24 rotates to a certain position or at an angle (e.g. the position 5b as shown), some portions of the periphery 24a of the plug-in part 24 are capable of abutting or resisting against some portions of the internal circumferential wall 5a of the recess 5. In this way, the plug-in part 24 driven by the rotation of the rotary mechanism M can push, force or drive the substrate carrier 3 to rotate synchronously in the direction of the horizontal plane defined by the X and Y-axes. It should be noted that, there is a clearance fit, rather than a tight friction fit in the prior art, between the plug-in part 24 and the recess 5 in the present application. That is, the rotation of the substrate carrier 3 in the present application is not realized by the friction fit between the plug-in part 24 and the recess 5. Furthermore, in the present application, the supporting surface 22a of the supporting part 22 supports the second surface 3b of the substrate carrier 3 in the Z-axis direction, so as to achieve the supporting of the substrate carrier 3, Accordingly, after the substrate carrier 3 is placed on the supporter 2, a certain clearance is allowed to exist between a top surface 5c of the recess 5 and a top surface 24c of the plug-in part 24 (practically, the clearance may also not exist). In other words, plug-in part 24 protrudes outwardly from the supporting surface 22a by a certain distance (the vertical distance between the supporting surface 22a and the top surface 24c of the plug-in part 24), and the distance is smaller than or equal to the depth of the recess 5 concaved inwardly (the vertical distance between the second surface 3b and the top surface 5c of the recess 5).

It can be known from the above description that, in the reactor according to the present application, on the one hand, since the space surrounded by the internal circumferential wall 5a of the recess 5 of the substrate carrier 3 is larger than the periphery 24a of the plug-in part 24 of the supporter 2, there is a clearance between the plug-in part 24 and the recess 5, so that the plug-in part 24 can be inserted into or detached from the recess 5 easily, and optionally, the plug-in part 24 may further rotate by a certain angle or move by a certain distance in the recess 5, and then arrive at a specific position in the recess 5 by designing the shape or size of the periphery 24a of the plug-in part 24 and the internal circumferential wall 5a of the recess 5, and at the specific position, some portions of the plug-in part 24 abut or resist against or lock some portions of the internal circumferential wall 5a of the recess 5 so that the plug-in part 24 becomes a “driving mechanism” under the action of the rotary mechanism M, i.e., the plug-in part 24 may drive or push the recess 5 to rotate synchronously on the plane defined by the X and Y-axes; and on the other hand, the supporter 2 according to the present application is further provided with the supporting part 22 like the structure of “a shoulder” or “a supporting shelf” so as to stably support the substrate carrier 3 in the Z-axis direction. When the substrate carrier 3 is placed on the supporter 2 and a substrate processing is performed, the rotation movement of the substrate carrier 3 is achieved in that the plug-in part 24 of the supporter 2 pushes or forces the substrate carrier 3 in the direction of the horizontal plane, while the supporting part 22 bears the overall weight of the substrate carrier 3 stably in the vertical direction.

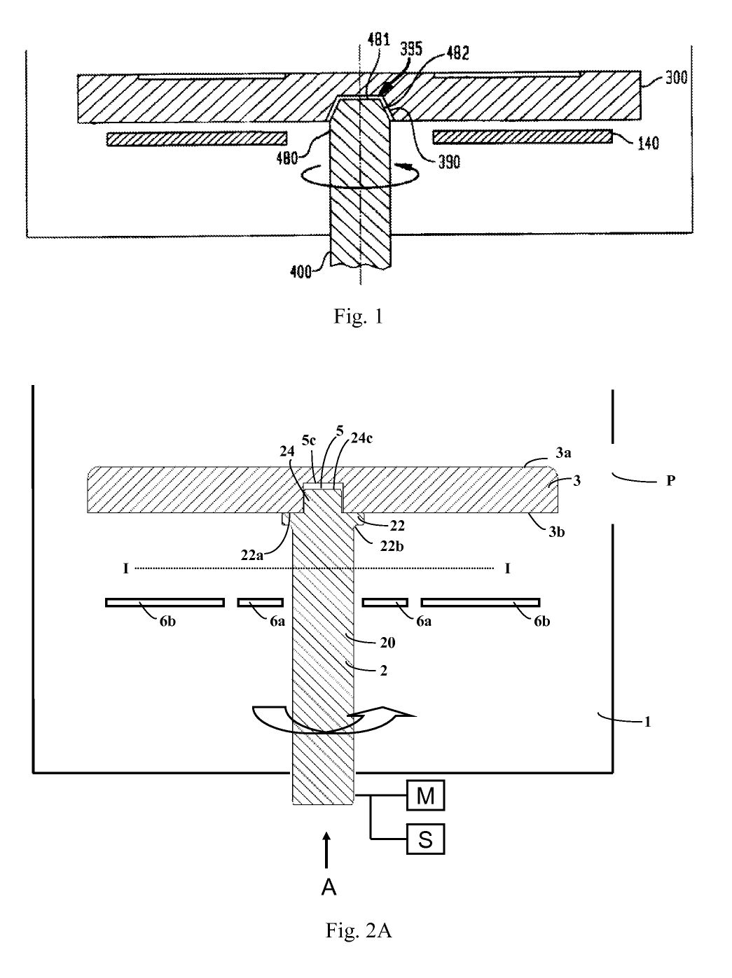

Compared with the reactor in the prior art as shown in FIG. 1, the reactor in the present application has many advantages. First, after the substrate carrier 3 is placed on the supporter 2, the whole substrate carrier 3 is supported by the supporting surface 22a of the supporting part 22 of the supporter 2, thus being a “surface supporting”, which is different from a “point contact supporting” in the prior art. In this way, the whole substrate carrier 3 of the present application cannot sway from side to side due to the instability of gravity center in a substrate processing after being placed on the supporter 2. Furthermore, since the rotation of the substrate carrier 3 is realized under the force (pushing force or resisting force) applied by the plug-in part 24 in the direction of the horizontal plane, the phenomenon of “friction slipping” between the substrate carrier and the plug-in part in the prior art may not arise. Further, since there is a certain clearance between the plug-in part 24 and the recess 5 after they are connected and engaged with each other, the clearance allows the thermal expansion of the plug-in part 24 in a high-temperature processing environment, thereby preventing the damages to the brittle substrate carrier 3 under the expansion pressure of the plug-in part 24 expanded thermally due to the friction fit therebetween, which would be otherwise occur in the prior art. Lastly, the arrangement of the present application may further facilitate measuring the exact position and temperature of the substrates located in the enclosed reaction chamber 1 in real time and in situ in a substrate processing. As shown in FIG. 2A, a speed sensor S is connected to the supporter 2. Since the supporter 2 and the substrate carrier 3 according to the present application rotate at the same speed, the rotation speed of the substrate carrier 3 can be obtained by measuring the rotation speed of the supporter 2, and thus the relative position of each substrate in rotation can be accurately calculated. Based on the accurate position, the pyrometer arranged in the reaction chamber 1 to measure the temperature of the substrates may accurately measure and calculate the temperature of the substrates in high-speed rotation in the reaction chamber.

In the above-mentioned reaction chamber 1, a heater is further provided under the substrate carrier 3 to heat the substrates on the substrate carrier 3. In order to heat the substrate uniformly, a first heater 6a and a second heater 6b may be provided under the substrate carrier 3. The first heater 6a is arranged close to the supporter 2. For example, The first heater 6a may be an annular heater around the periphery of the spindle part 20 and placed in the horizontal direction as shown; or may be arranged around the periphery of the spindle part 20 in a vertical direction (not shown) and close to the supporting part 22, so as to solve the problem of the poor heated effect of the part of the substrate carrier 3 (i.e. the central portion of the substrate carrier 3) contacting with the supporting part 22 due to the blocking of supporting part 22. The second heater 6b is arranged outside of the first heater 6a to heat the edge portion of the substrate carrier 3. Preferably, each of the first heater 6a and the second heater 6b is communicated with a heating control signal so as to provide the heating control separately.

Optionally, the above-mentioned supporting part 22 may also be provided with a hollowed-out structure of a specific shape. For example, the supporting part 22 as shown in FIG. 2A includes a supporting surface 22a and a bottom surface 22b, and the hollowed-out structure (not shown) may extends through the supporting surface 22a and the bottom surface 22b, so that the heat from the first heater 6a passes through the hollowed-out structure to heat the substrate carrier 3 directly. Thus, the effect of heating the whole substrate carrier 3 uniformly may be achieved by using only one heater. The specific shape and distribution of the hollowed-out structure may be designed according to actual demands, for example, it may be designed as multiple hollowed-out annular grooves, through holes, through grooves or the like, which may be evenly or unevenly distributed on the supporting part 22.

Optionally, the above-mentioned supporting surface 22a of the supporting part 22 or the contacting surface 3b of the substrate carrier 3 being in contact with the supporting surface 22a may also be designed as a rough surface, or some structures capable of being engaged mutually may also be provided on the two surfaces. For example, some structures for increasing the friction force are provided on the two surfaces, so as to improve the supporting effect of the supporter 2 on the substrate carrier 3.

It should be appreciated that, according to the spirit of the present application, the plug-in part and the recess illustrated above may have various embodied modifications. For example, the plug-in part of the supporter may be designed as an elliptic cylinder, a circular cylinder, a rectangular parallelepiped or a cube. The cross section of the recess in the direction of the horizontal plane may be elliptic, rectangular, square, circular or triangular in shape.

As shown in FIG. 3B, it is a schematic cross-sectional bottom view of a reactor according to another embodiment of the present application. This embodiment is different from that shown in FIG. 3A in that, a plug-in part 34 in FIG. 3B is an approximate rectangular parallelepiped having a rectangular cross section in the horizontal plane, and a cavity formed in a concaved recess 7 is also a rectangular parallelepiped having a rectangular cross section in a horizontal plane. The plug-in part 34 includes a periphery 34a, and the recess 7 of the substrate carrier 3 includes an internal circumferential wall 7a. The area of the cross section surrounded by the periphery 34a of the plug-in part 34 is smaller than or slightly smaller than the area of the cross section surrounded by the internal circumferential wall 7a of the recess 7. Thus, the plug-in part 34 can be easily inserted into the recess 7, and there is a certain clearance therebetween after they are engaged with each other. In addition, since the plug-in part 34 may be driven to rotate by the rotary mechanism M located under the plug-in part 34, so that the position of the plug-in part 34 can be adjusted. When the plug-in part 34 rotates to a certain position or at an angle (e.g. the position 7b as shown), some portions of the periphery 34a of the plug-in part 34 are capable of abutting or resisting against some portions of the internal circumferential wall 7a of the recess 7. In this way, the plug-in part 34 driven by the rotation of the rotary mechanism M can push, force or drive the substrate carrier 3 to rotate synchronously in the horizontal direction.

As shown in FIG. 3C, it is a schematic cross-sectional bottom view of a reactor according to another embodiment of the present application. This embodiment is different from that shown in FIGS. 3A and 3B in that, at least one key or positioning pin 44b is provided on the plug-in part 44 in FIG. 3C, and a groove 8b matched with the key or positioning pin 44b is provided on a side wall of a recess 8 of the substrate carrier 3. When the plug-in part 44 is inserted into the recess 8, the key or positioning pin 44b is at least partially engaged with or contacts with the groove 8b, so as to enable the synchronous movement of the plug-in part 44 and the recess 8. Similar to the aforementioned discussion, there is a certain clearance between the periphery of the plug-in part 44 and the internal circumferential wall of the recess 8.

It should be appreciated that, the number of the plug-in part in the various embodiments mentioned above is not limited to one, but may be two or more; and the number of the recess described above is not limited to one, but may be two or more, so long as the one or more plug-in parts can be inserted detachably in one or more recess, and at a certain position, the one or more plug-in parts can at least partially contact with, be engaged with or abut against at least parts of the one or more recesses.

In the above-mentioned embodiments, the plug-in parts of the various supporters are configured to be connected with the supporting parts and protrude outwardly by a certain distance or height from the supporting surfaces to positions where the plug-in parts can be engaged with the various recesses mentioned above respectively. It should be appreciated that the plug-in parts in the present application may also be arranged at other positions of the spindle part. For example, taking FIG. 2C as an example, the plug-in part 24 in the embodiment as shown may be modified such as to extend upwardly from a certain position 20a of the spindle part 20 located below the supporting part 22 to a position where the plug-in part can be engaged with the various recesses mentioned above. The number of the extended plug-in part may be one or more. The position of the recess may be adapted to be in a configuration corresponding to the plug-in part.

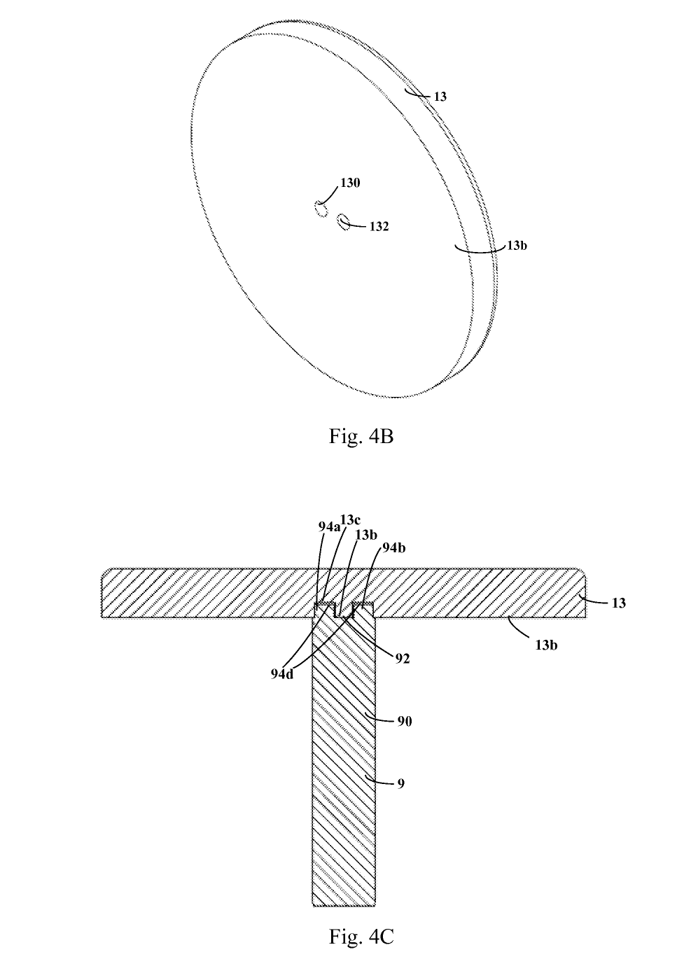

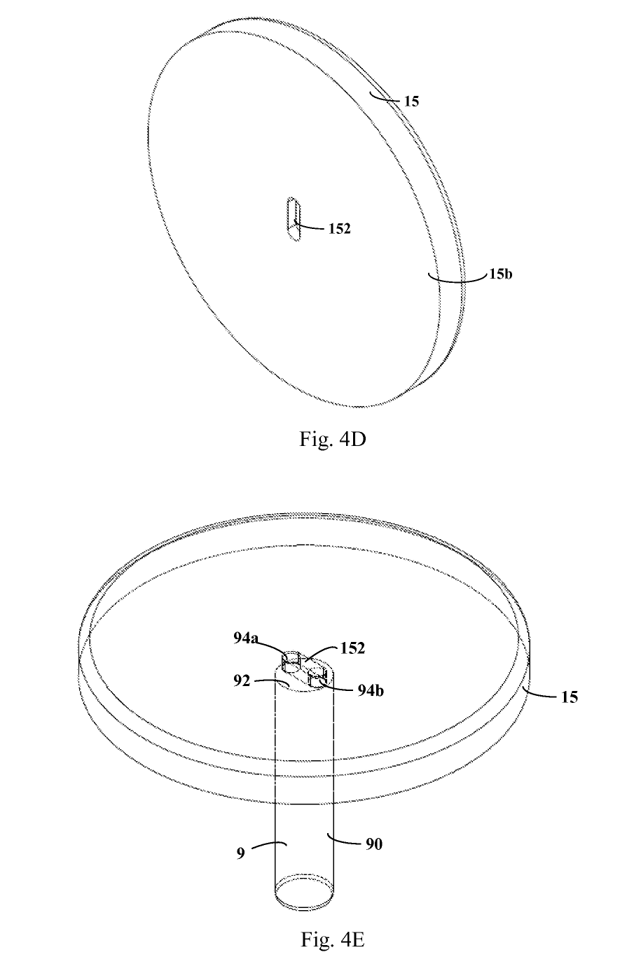

Further, according to the sprit and nature of the present application, the above-mentioned plug-in parts and recesses may also be modified in the following embodiments. As shown in FIGS. 4A to 4C, FIGS. 4A and 4B are schematic perspective views of a supporter and a substrate carrier according to other embodiments of the present application respectively; and FIG. 4C is a schematic cross-sectional view illustrating the connection between the supporter shown in FIG. 4A and the substrate carrier shown in FIG. 4B. The embodiment shown in FIG. 4A is different from those in the above-mentioned embodiments in that, a supporter 9 as shown in FIG. 4A does not includes a supporting part extending outwardly from the spindle part by a certain distance, but is provided with a supporting surface 92 directly on the top end 90a of a spindle part 90 thereof; and one, two or more plug-in parts 94a, 94b are provided on the supporting surface 92. It should be appreciate that, according to different design demands, the two or more plug-in parts may be spaced apart from each other by a distance or adjacent to each other. Accordingly, a substrate carrier 13 includes a second surface 13b on which one, two or more recesses 130, 132 concaved inwardly are provided. In a similar way, according to different design demands, the two or more recesses may be spaced apart from each other by a distance or adjacent to each other, and correspond to the positions of the two or more plug-in parts described above so as to facilitate the engagement of them. Similarly, the plug-in parts 94a, 94b may be inserted detachably into the recesses 130, 132, and there is a clearance between the plug-in parts and the recesses after they are engaged, thereby detaching the plug-in parts 94a, 94b easily from the recesses 130, 132. After the substrate carrier 13 is placed on the supporter 9, at least a part of the second surface 13b of the substrate carrier 13 are in contact with the supporting surface 92 of the supporter 9, so that the weight of the whole substrate carrier 13 is supported by the supporting surface 92. At a certain position, the plug-in parts 94a, 94b can at least partially contact with, be engaged with or abut against at least parts of the recesses 130, 132, so that the plug-in parts 94a, 94b driven by the rotation of the rotary mechanism M can push, force or drive the substrate carrier 13 to rotate synchronously in the direction of the horizontal plane.

In order to provide better supporting effect, the top end 90a of the spindle part 90 may be arranged to have a relatively large diameter. Thus, the area of the supporting surface 92 is relatively large, therefore providing a more stable supporting to the substrate supporter 13.

The above-mentioned recesses 130, 132 shown in FIG. 4B may be modified as a single recess structure. As shown in FIGS. 4D and 4E, FIG. 4D is a schematic perspective view of a substrate carrier according to another embodiment of the present application; and FIG. 4E is a schematic perspective view illustrating the connection and engagement between the supporter shown in FIG. 4A and the substrate carrier shown in FIG. 4D. A substrate carrier 15 includes a second surface 15b, and an approximate elongated recess 152 (a groove with two rounded ends in the embodiment as shown) is provided at a proper position (a central region as shown) of the second surface 15b. The elongated recess 152 is sized to accommodate the plug-in parts 94a, 94b as shown in FIG. 4A. In the same way, the plug-in parts 94a, 94b can be inserted detachably into the recess 152. As shown in FIG. 4E, when the substrate carrier 15 is placed on the supporter 9 shown in FIG. 4A, at least a part of the second surface 15b of the substrate carrier 15 are in contact with the supporting surface 92 of the supporter 9, so that the weight of the whole substrate carrier 15 is supported by the supporting surface 92. At a certain position, the plug-in parts 94a, 94b can at least partially contact with, be engaged with or abut against at least parts of the recess 152, so that the plug-in parts 94a, 94b driven by the rotation of the rotary mechanism M can push, force or drive the substrate carrier 15 to rotate synchronously in the direction of the horizontal plane.

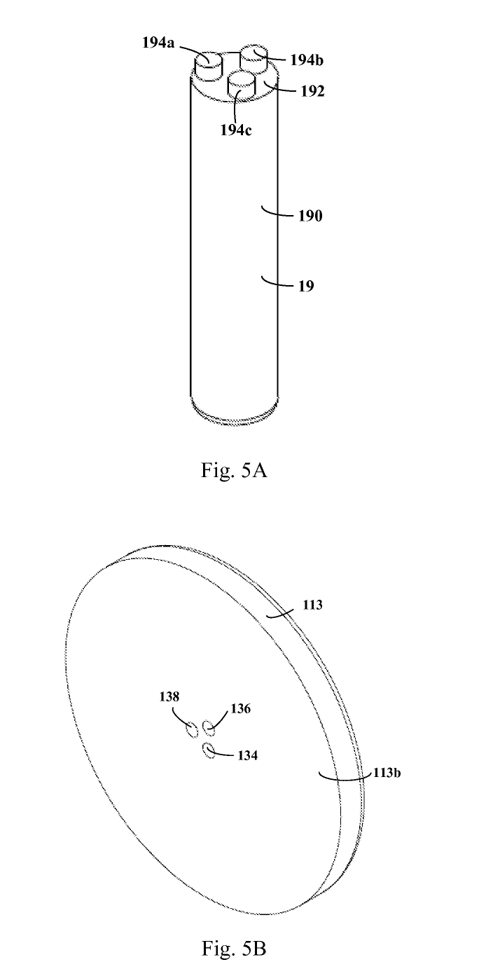

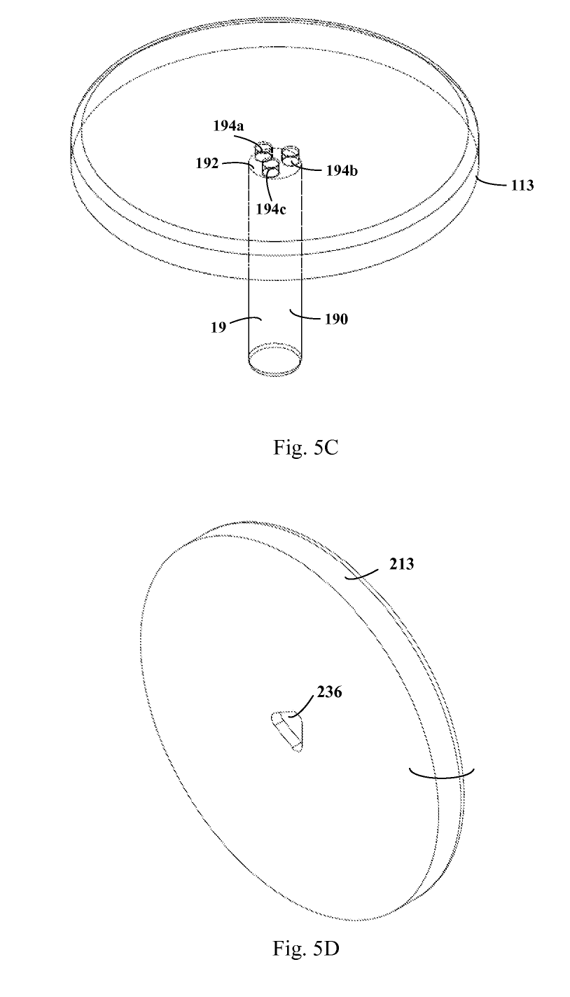

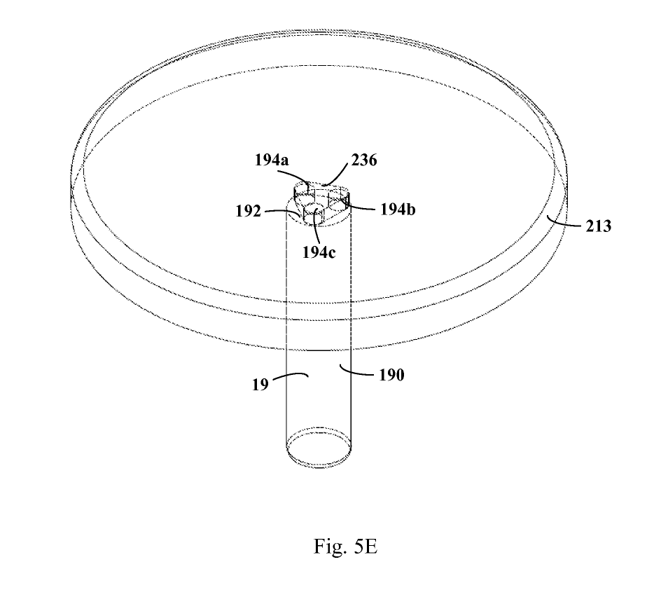

Please refer to FIGS. 5A to 5C, FIGS. 5A and 5B are schematic perspective views of a supporter and a substrate carrier according to other embodiments of the present application respectively; and FIG. 5C is a schematic perspective view illustrating the connection and engagement between the supporter shown in FIG. 5A and the substrate carrier shown in FIG. 5B. The supporter 19 shown in FIG. 5A includes a spindle part 190. The spindle part 190 includes a top end including a supporting surface 192. Three plug-in parts 194a, 194b, 194c are provided on the supporting surface 192. Accordingly, a substrate carrier 113 shown in FIG. 5B includes a second surface 113b on which three recesses 134, 136, 138 concaved inwardly are provided. Compared with the embodiment shown in FIG. 4E, in FIG. 5C the three plug-in parts 194a, 194b, 194c and the corresponding three recesses 134, 136, 138 concaved inwardly may be connected and engaged with each other to provide a more stable connection so that the plug-in parts 194a, 194b, 194c may push or drive the substrate carrier 113 to rotate in the direction of the horizontal plane more smoothly and reliably.

Please further referring to FIGS. 5D and 5E, FIG. 5D is a schematic perspective view of a substrate carrier according to another embodiment of the present application; and FIG. 5E is a schematic perspective view illustrating the connection and engagement between the supporter shown in FIG. 5A and the substrate carrier shown in FIG. 5D. A substrate carrier 213 includes a second surface 213b, and a recess 236 concaved inwardly having an approximate triangular cross section is provided on the second surface 213b. As shown in FIG. 5E, when the substrate carrier 213 is placed detachably on the supporter 19 shown in FIG. 5A, the plug-in parts 194a, 194b, 194c are all accommodated in the recess 236. Similarly, the plug-in parts 194a, 194b, 194c may be located at a certain position where at least parts of the peripheries of the plug-in parts 194a, 194b, 194c may contact with, be engaged with or abut against at least parts of the internal circumferential wall of the recess 236. In this case, when the supporter 19 rotates under the action of the rotary mechanism M, the plug-in parts 194a, 194b and 194c can drive or push the recess 236 to rotate synchronously in the direction of the horizontal plane; and meanwhile, the weight of the whole substrate carrier 213 is supported by the supporting surface 192 of the supporter 19.

In any of the various embodiments shown in FIGS. 4A to 5E, the supporting of the substrate carrier may be achieved in that the supporting surface of the top end of the spindle part supports the second surface of the substrate carrier in the Z-axis direction. Accordingly, after the substrate carrier is placed on the supporter, a certain clearance is allowed to exist between the top surface (13c in FIG. 4C) of the recess and the top surface (94d in FIG. 4C) of the plug-in parts. Practically, the clearance may also be zero in actual design.

It should be appreciated that, the plug-in parts in the various embodiments mentioned above are not limited to be arranged in the central region of the supporting surface, but may be arranged or distributed in the edge region of the supporting surface, or may be distributed both in the central region and in the edge region. The recesses of the substrate carriers in the various embodiments mentioned above are not limited to be arranged in the central region of the second surface thereof, but may be arranged or distributed in the edge region of the second surface, or may be distributed both in the central region and in the edge region.

In any of the various embodiments in FIGS. 4A to 5E mentioned above, the plug-in parts of the supporter are configured to be connected with the top end of the spindle part and protrude outwardly by a certain distance or height from the supporting surface to a position where the plug-in parts can be engaged with the recess(es) mentioned above. It should be appreciated that, the plug-in parts in these embodiments may be provided at other positions of the spindle part. For example, the plug-in part may be configured to be connected to another position of the spindle part and extend towards the first surface of the above substrate carrier by a height to a position where the plug-in part can be engaged with the above recess. Taking FIG. 4A as an example, the plug-in parts 94a, 94b in the embodiment as illustrated may be modified such as to extend upwardly from a certain position 90b of the spindle part 90 located below the supporting surface 92 to a position where the plug-in parts can be engaged with the recess(es) mentioned above. The number of the extended plug-in part may be one or more. Accordingly, the position of the recess may be adapted in a configuration corresponding to the plug-in part, so as to facilitate the engagement therebetween.

It should be further appreciated that, the various structures of plug-in parts and recesses illustrated in FIGS. 2A to 3C may be deemed as modifications of the structures of plug-in parts and recesses in the embodiments illustrated in FIGS. 4A to 5E; and the various structures of plug-in parts and recesses illustrated in FIGS. 4A to 5E may also be deemed as modifications of the structures of plug-in parts and recesses in the embodiments illustrated in FIGS. 2A to 3C, the operating principles of which are the same, and will not be described repeatedly herein. All these modifications fall into the scope of claims of the present application.

Preferably, several hollowed-out structures or cutouts (not shown) may be provided in the above-mentioned spindle part 90 or 190 and close to the supporting surface 92 or 192. These hollowed-out structures or cutouts may facilitate the direct conduction and radiation of the heat from the heater located under the substrate carrier 13 or 113 to the second surface of the substrate carrier 13 or 113.

It should be appreciated that, in the various embodiments mentioned above, though the supporting surface as illustrated is schematically shown as a horizontal surface, but not limited to such design. The supporting surface may also be designed to be an inclined surface at a certain angle with respect to the horizontal plane, or any other irregular surface. Some concave or convex structures or other structures increasing the surface roughness may further be provided on the supporting surface; and accordingly, some structures matched with the structures on the supporting surface may be provided on the second surface of the substrate carrier so as to facilitate the contact and support therebetween.

Preferably, the edge portion of the plug-in part in the various embodiments mentioned above may be designed to be rounded or chamfered for facilitating the engagement between the plug-in part and the recess; and accordingly, the recess in the various embodiments mentioned above may also be designed to be rounded or chamfered for facilitating the engagement between the plug-in part and the recess.

Compared with the reactor in the prior art as shown in FIG. 1, the reactor in the present application has many advantages: First, after the substrate carrier is placed on the supporter, the whole substrate carrier is supported by the supporting surface of the supporter, thus being a “surface supporting”, which may increase the bearing area of the supporter effectively and is different from a “point contact supporting” in the prior art. In this way, the whole substrate carrier of the present application cannot sway from side to side due to the instability of gravity center in the substrate processing after being placed on the supporter, that is, the supporter can force the substrate carrier to rotate synchronously and smoothly. Furthermore, since the rotation of the substrate carrier is realized under the force (pushing force or resisting force) applied by the plug-in part in the direction of the horizontal plane, thereby, the phenomenon of “friction slipping” between the substrate carrier and the plug-in part in the prior art may not arise. Further, since a certain clearance is allowed to exist between the plug-in part and the recess after they are connected and engaged with each other, the clearance allows the thermal expansion of the plug-in part 24 in a high-temperature processing environment, thereby preventing the damages to the substrate carrier under the pressure of the plug-in part heated and thus expanded due to the friction fit therebetween which would be otherwise occur in the prior art. Lastly, the arrangement of the present application may further facilitate measuring the exact position and temperature of the substrates located in the enclosed reaction chamber in real time and in situ in a substrate processing.

Although the present application is disclosed above by the preferred embodiments, these preferred embodiments are not intended to limit the application. Possible variations and modifications can be made by any skilled in the art without departing from the spirit and scope of the present application defined by the claims thereof.

What is claimed is:

1. A chemical vapor deposition or epitaxial-layer growth reactor, comprising a reaction chamber in which a substrate carrier and a supporter for supporting the substrate carrier are provided, wherein
the substrate carrier comprises a first surface and a second surface, the first surface is configured to place several substrates to be processed thereon; the second surface of the substrate carrier is provided with at least one recess concaved inwardly;
the supporter comprises: a spindle part; a supporting part connected to one end of the spindle part and extending outwardly from the periphery of the spindle part, the supporting part comprising a supporting surface; and at least one plug-in part connected to the spindle part and extending by a height towards the first surface of the substrate carrier; and
the at least one plug-in part of the supporter is inserted detachably into the at least one recess, so as to enable the substrate carrier to be placed on and supported by the supporter, and in a supporting case, the supporting surface of the supporting part at least partially contacts with at least a part of the second surface of the substrate carrier, so that the substrate carrier is supported by the supporting surface in contact with the substrate carrier.

2. The reactor according to claim 1, wherein the at least one plug-in part of the supporter is connected to the supporting part, and protrudes outwardly by a distance from the supporting surface to a position where the at least one plug-in part is allowed to be engaged with the at least one recess.

3. The reactor according to claim 1, wherein the at least one plug-in part of the supporter is connected to a position of the spindle part located below the supporting surface, and extends by a height towards the first surface of the substrate carrier to a position where the at least one plug-in part is allowed to be engaged with the at least one recess.

4. The reactor according to claim 1, wherein the at least one plug-in part of the supporter comprises a periphery, and the at least one recess of the substrate carrier comprises an internal circumferential wall; when the at least one plug-in part of the supporter is inserted into the at least one recess, there is a clearance between at least parts of the periphery and the internal circumferential wall, and the at least one plug-in part is located in the at least one recess at a position where at least a part of the periphery contacts with, is engaged with or abuts against at least a part of the internal circumferential wall.

5. The reactor according to claim 1, wherein the at least one plug-in part of the supporter comprises a first plug-in part and a second plug-in part spaced apart from each other or adjacent to each other.

6. The reactor according to claim 5, wherein the at least one recess comprises a first recess and a second recess; and wherein, when the at least one plug-in part of the supporter is inserted into the at least one recess, the first plug-in part is inserted into the first recess, and the second plug-in part is inserted into the second recess.

7. The reactor according to claim 5, wherein the at least one recess includes a single recess sized or shaped such that at least one of the first plug-in part and the second plug-in part is accommodated in the recess when the at least one plug-in part of the supporter is inserted in the at least one recess.

8. The reactor according to claim 1, wherein at least one key or positioning pin is provided on the at least one plug-in part of the supporter, and at least one groove matched with the at least one key or positioning pin is provided on a side wall of the at least one recess of the substrate carrier; and
wherein, when the at least one plug-in part of the supporter is inserted into the at least one recess, the at least one key or positioning pin is at least partially engaged with, contacts with or abuts against the at least one groove, so as to enable synchronous movement of the at least one plug-in part and the at least one recess.

9. The reactor according to claim 1, wherein the at least one recess comprises a first recess and a second recess distributed on the second surface of the substrate carrier, and spaced apart from each other by a distance or adjacent to each other.

10. The reactor according to claim 1, wherein several hollowed-out structures are provided in the supporting part of the supporter.

11. The reactor according to claim 1, wherein the spindle part of the supporter is connected to a rotary mechanism, so as to be rotated by the rotary mechanism, and the at least one plug-in part connected to the spindle part forces, pushes or drives the substrate carrier to rotate.

12. A chemical vapor deposition or epitaxial-layer growth reactor, comprising a reaction chamber in which a substrate carrier and a supporter for supporting the substrate carrier are provided, wherein
the substrate carrier comprises a first surface and a second surface, the first surface is configured to place several substrates to be processed thereon; the second surface of the substrate carrier is provided with at least one recess concaved inwardly;
the supporter comprises: a spindle part comprising a top end, the top end comprising a supporting surface; and at least one plug-in part connected to the spindle part and extending by a height towards the first surface of the substrate carrier; and
the at least one plug-in part is inserted detachably into the at least one recess, so as to enable the substrate carrier to be placed on and supported by the supporter, and in a supporting case, the supporting surface at least partially contacts with at least a part of the second surface of the substrate carrier, so that the substrate carrier is supported by the supporting surface in contact with the substrate carrier.

13. The reactor according to claim 12, wherein the at least one plug-in part of the supporter is connected to the top end, and protrudes outwardly by a distance from the supporting surface to a position where the at least one plug-in part is allowed to be engaged with the at least one recess.

14. The reactor according to claim 12, wherein the at least one plug-in part of the supporter is connected to a position of the spindle part located below the supporting surface, and extends by a height towards the first surface of the substrate carrier to a position where the at least one plug-in part is allowed to be engaged with the at least one recess.

15. The reactor according to claim 12, wherein the at least one plug-in part of the supporter comprises a periphery, and the at least one recess of the substrate carrier comprises an internal circumferential wall; when the at least one plug-in part of the supporter is inserted into the at least one recess, there is a clearance between at least parts of the periphery and the internal circumferential wall, and the at least one plug-in part of the supporter is located in the at least one recess at a position where at least a part of the periphery contacts with, is engaged with or abuts against at least a part of the internal circumferential wall.

16. The reactor according to claim 12, wherein the at least one plug-in part of the supporter comprises a first plug-in part and a second plug-in part spaced apart from each other by a distance or adjacent to each other.

17. The reactor according to claim 16, wherein the at least one recess comprises a first recess and a second recess; and wherein, when the at least one plug-in part of the supporter is inserted into the at least one recess, the first plug-in part is inserted into the first recess, and the second plug-in part is inserted into the second recess.

18. The reactor according to claim 16, wherein the at least one recess is sized or shaped such that at least one of the first plug-in part and the second plug-in part is accommodated in the at least one recess when the at least one plug-in part of the supporter is inserted in the at least one recess.

19. The reactor according to claim 12, wherein at least one key or positioning pin is provided on the at least one plug-in part of the supporter, and at least one groove matched with the at least one key or positioning pin is provided on a side wall of the at least one recess of the substrate carrier; and
wherein, when the at least one plug-in part of the supporter is inserted into the at least one recess, the at least one key or positioning pin is at least partially engaged with or contacts with the at least one groove, so as to enable synchronous movement of the at least one plug-in part and the at least one recess.

20. The reactor according to claim 12, wherein the at least one recess comprises a first recess and a second recess distributed on the second surface of the substrate carrier, and spaced apart from each other by a distance or adjacent to each other.
